(19) United States
(12) Patent Application Publication
(10) Pub. No.: US 2025/0257461 A1
(43) Pub. Date: Aug. 14, 2025

(54) METAL ORGANIC RESIST PHOTOSENSITIVITY IMPROVEMENT USING ORGANOTIN AMIDE AND ORGANOTIN ALKOXIDE

(71) Applicant: MERCK PATENT GmbH, DARMSTADT (DE)

(72) Inventors: XINJIAN LEI, VISTA, CA (US); ANGELICA AZCATL ZACATZI, SAN JOSE, CA (US); CHILIANG CHEN, SUNNYVALE, CA (US)

(21) Appl. No.: 19/046,962

(22) Filed: Feb. 6, 2025

Related U.S. Application Data
(60) Provisional application No. 63/553,065, filed on Feb. 13, 2024.

(51) Int. Cl. C23C 16/455; C23C 16/44; G03F 7/004; G03F 7/16

(52) U.S. Cl. CPC C23C 16/45553; C23C 16/4408; G03F 7/0042; G03F 7/167

(57) ABSTRACT

The disclosed and claimed subject matter relates to a method for depositing tin-containing films that includes the steps of (a) contacting a substrate with organotin alkoxide precursor vapor in a deposition reactor, (b) thereafter introducing an organotin amide precursor vapor in a deposition reactor wherein the organo group is different from the organo group in the organotin alkoxide precursor, (c) purging the reactor vessel with inert gas, (d) contacting the substrate with a water-containing vapor to form an organotin oxo network layer, (e) purging the reactor vessel with inert gas.

### CROSS-REFERENCE TO RELATED APPLICATION

This application claims the benefit of priority under 35 USC § 119 of U.S. Provisional Application No. 63/553,065 (filed on 13 Feb. 2024) which application is incorporated herein by reference in its entirety.

### BACKGROUND

### Field

The disclosed and claimed subject matter relates to a method for depositing tin-containing films. The method generally includes (a) contacting a substrate with organotin alkoxide precursor vapor in a deposition reactor, (b) thereafter introducing an organotin amide precursor vapor in a deposition reactor wherein the organo group is different from the organo group in the organotin alkoxide precursor, (c) purging the reactor vessel with inert gas, (d) contacting the substrate with a water-containing vapor to form an organotin oxo network layer, (e) purging the reactor vessel with inert gas. The processing steps can be repeated may be repeated to provide a desired thickness of organotin oxo films.

### Related Art

Thin films, and in particular thin metal-containing films, have a variety of important applications, such as in nanotechnology and the fabrication of semiconductor devices. Examples of such applications include conducting metal oxides, EUV patterning, high-refractive index optical coatings, corrosion-protection coatings, photocatalytic self-cleaning glass coatings, biocompatible coatings, dielectric capacitor layers and gate dielectric insulating films in field-effect transistors (FETs), capacitor electrodes, gate electrodes, adhesive diffusion barriers, and integrated circuits. Metallic thin films and dielectric thin films are also used in microelectronics applications, such as the high-κ dielectric oxide for dynamic random-access memory (DRAM) applications and the ferroelectric perovskites used in infrared detectors and non-volatile ferroelectric random-access memories (NV-FeRAMs).

Various precursors may be used to form metal-containing thin films and a variety of deposition techniques can be employed. Such techniques include reactive sputtering, ion-assisted deposition, sol-gel deposition, chemical vapor deposition (CVD) (also known as metalorganic CVD or MOCVD), and atomic layer deposition (ALD) (also known as atomic layer epitaxy). CVD and ALD processes are increasingly used as they have the advantages of enhanced compositional control, high film uniformity, and effective control of doping.

CVD is a chemical process whereby precursors are used to form a thin film on a substrate surface. In a typical CVD process, the precursors are passed over the surface of a substrate (e.g., a wafer) in a low pressure or ambient pressure reaction reactor. The precursors react and/or decompose on the substrate surface creating a thin film of deposited material. Volatile by-products are removed by gas flow through the reaction reactor. The deposited film thickness can be difficult to control because it depends on coordination of many parameters such as temperature, pressure, gas flow volumes and uniformity, chemical depletion effects, and time.

ALD is also a method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are introduced separately during the deposition. The first precursor is passed over the substrate surface producing a monolayer on the substrate surface. Any excess unreacted precursor is pumped out of the reaction reactor. A second precursor is then passed over the substrate surface and reacts with the first precursor, forming a second monolayer of film over the first-formed monolayer of film on the substrate surface. This cycle is repeated to create a film of desired thickness.

CVD and ALD are specifically attractive for fabricating metal containing films on substrates, such as silicon, silicon oxide, metal nitride, metal oxide and other metal-containing layers, using these metal-containing precursors. As noted above, in these techniques, a vapor of a volatile metal complex is introduced into a process reactor where it contacts the surface of a silicon wafer whereupon a chemical reaction occurs that deposits a thin film of pure metal or a metal compound. CVD occurs if the precursor reacts at the wafer surface either thermally or with a reagent added simultaneously into the process reactor and the film growth occurs in a steady state deposition. CVD can be applied in a continuous or pulsed mode to achieve the desired film thickness. In ALD, the precursor is chemisorbed onto the wafer as a self-saturating monolayer, excess unreacted precursor is purged away with an inert gas such as argon, then excess reagent is added which reacts with the monolayer of chemisorbed precursor to form metal or a metal compound. Excess reagent is then purged away with inert gas. This cycle can then be repeated multiple times to build up the metal or metal compound to a desired thickness with atomic precision since the chemisorption of precursor and reagent are self-limiting. ALD provides the deposition of ultra-thin yet continuous metal containing films with precise control of film thickness, excellent uniformity of film thickness and outstandingly conformal film growth to evenly coat deeply etched and highly convoluted structures such as interconnect vias and trenches. Thus, ALD is typically preferred for deposition of thin films on features with high aspect ratio.

Suitable metal precursors for ALD include those which are thermally stable to preclude any thermal decomposition occurring during the chemisorption stage yet are chemically reactive towards added reagent. Additionally, it is important that the metal precursors are monomeric for maximum volatility and clean evaporation leaving only a trace of involatile residue. It is also desirable that the precursors are liquid at room temperature.

CVD/ALD processes using organotin compounds as precursors and an oxygen source such as water vapor or organic co-reactant to deposit MOR materials are known. For example:

WO22016123 A1 discloses a film formed with a precursor and an organic co-reactant, as well as methods for forming and employing such films. The film can be employed as a photopatternable film or a radiation-sensitive film. In some embodiments, the carbon content within the film can be tuned by decoupling the sources of the radiation-sensitive metal elements and the radiation-sensitive organic moieties during deposition. In non-limiting embodiments, the radiation can include extreme UV (EUV) or deep UV (DUV) radiation.

WO2022016128 discloses methods of forming photosensitive metal-polymer hybrid photoresist films for photolitography to improve extreme UV sensitivity and patterning quality are discussed. The method involves depositing a metal-containing layer on a surface of a substrate by providing a metal precursor to the surface, wherein the substrate is disposed within a chamber; purging the metal precursor from the chamber; and depositing an organic layer on a surface of the metal-containing layer by providing an organic precursor to the surface, where the organic layer comprises a photosensitive organic moiety, thereby forming a patterning radiation-sensitive film.

US2022155689A discloses a method of depositing a photoresist onto a substrate in a processing chamber. In an embodiment, the method includes flowing an oxidant into the processing chamber through a first path in a showerhead and flowing an organometallic into the processing chamber through a second path in the showerhead. In another embodiment, the first path is isolated from the second path so that the oxidant and the organometallic do not mix within the showerhead. In yet another embodiment, the method further comprises that the oxidant and the organometallic react in the processing chamber to deposit the photoresist on the substrate.

US2022262625 discloses methods of depositing a metal oxo photoresist using chemical vapor condensation deposition processes over a substrate in a vacuum chamber includes providing a metal precursor vapor into the vacuum chamber from an ampoule maintained at a first temperature the method further includes providing an oxidant vapor into the vacuum chamber, where a reaction between the metal precursor vapor and the oxidant vapor results in the formation of the photoresist layer on a surface of the substrate. the photoresist layer is a metal oxo containing material. The substrate is maintained at a second temperature less than the first temperature during the formation of the photoresist layer on the surface of the substrate.

US2022002869 discloses methods of depositing a metal oxo photoresist using dry deposition processes for forming a photoresist layer over a substrate in a vacuum chamber comprises providing a metal precursor vapor into the vacuum chamber, in an embodiment, the method further comprises providing an oxidant vapor into the vacuum chamber, where a reaction between the metal precursor vapor and the oxidant vapor gave the photoresist layer on a surface of the substrate.

US2022199406 discloses a method of forming a metal-oxo photoresist on a substrate. In one embodiment, the method includes repeating a deposition cycle, where each iteration of the deposition cycle includes: a) flowing a metal precursor into a chamber comprising the substrate; and b) flowing an oxidant into the chamber, where the oxidant and the metal precursor react to form the metal-oxo photoresist.

U.S. Ser. No. 10/732,505 discloses organometallic precursors for the formation of high-resolution lithography patterning coatings based on metal oxide hydroxide. The precursor compositions generally include ligands readily hydrolysable by water vapor or other oh source composition under modest conditions. The organometallic precursors generally include a radiation sensitive organo ligand to tin that can result in a coating that can be effective for high resolution patterning at relatively low radiation doses and is particularly useful for EUV patterning.

Mullings, M. N., et al., “Tin Oxide Atomic Layer Deposition from Tetrakis(dimethylamino)tin and Water.” J. Vac. Sci. Technol., 31(6) (2013) describes ALD of tin oxide by means of the precursor tetrakis(dimethylamino)tin and water as a counter-reactant at low temperature growth in the range of 30-200° C. on Si(100) and glass substrates. According to this article, high quality, amorphous SnO₂ films with moderately tunable optical properties are thus obtained by ALD at temps. as low as 30° C. using tin precursor and water.

US2021397085 discloses formation of imaging layers on the surface of a substrate which may be patterned using next generation lithog. techniques, and the resulting patterned film may be used as a lithography mask, for example, for production of a semiconductor device.

US2021013034 discloses methods for making thin-films on semiconductor substrates, which may be patterned using EUV, including mixing a vapor stream of an organometallic precursor with a vapor stream of a counter-reactant so as to form a polymerized organometallic material; and depositing the organometallic polymer-like material onto the surface of the semiconductor substrate. the mixing and depositing operations may be performed by chem. vapor deposition (CVD), atomic layer deposition (ALD), and ALD with a CVD component, such as a discontinuous, ALD-like process in which metal precursors and counter-reactants are separated in either time or space.

In general, the above prior has been focusing CVD or ALD organotin oxo films or tin oxide involving one organometallic precursor and an oxidants such as water. U.S. Ser. No. 10/732,505 describes the use of two organometallic precursors of formula RₙSnX₍₄₋ₙ₎ (where the organo groups “R” are described as “straight-chain and branch-chain alky, cyclo-alky, aryl, aryl, alkenyl, alkynyl, benzyl, and their fluorinated derivatives.”) followed by a second precursor of formula SnX₄ where all of the “X” ligands (e.g., —NMe₂ or —O^{t}Bu) are required to be the same. Although no specific examples of this process are described, U.S. Ser. No. 10/732,505 indicates that the second precursor—that does not include any R groups—is supplied to alter the R:Sn content ratio in order to affect film properties.

Notwithstanding the above, there still is a need for improved deposition methods using organotin compounds as precursors for the deposition of photosensitive materials with better photosensitivity for certain applications in semi-conductor industry such as patterning process especially involving EUV for future technology nodes. This disclosed and claimed subject matter provides an improved deposition method i.e., an ALD-like process in which three precursors (i.e., two organotin compounds, and water) unlike a typical ALD process only involving two precursors.

Described herein is a method for deposition of organotin oxo films film via thermal ALD-like process. It is believed that reactions between two organotin compounds and water vapor via sequentially introducing an organotin alkoxide and an organotin amide, followed by water can provide better photosensitive organotin oxo materials with improved photosensitivity, smoother film, and less particles. Importantly the two organotin compounds have different organo groups bonded to the tin atom, allowing the resulting organotin oxo films to potentially provide better photosensitivity over that described in the known art. In addition, the ALD-like process described herein has the following advantages: (a) a growth rate ranging from about 2 Å/cycle to 50 Å/cycle, about 2 Å/cycle to about 30 Å/cycle, and about 2 Å/cycle to about 50 Å/cycle (compared to the growth rate of a typical ALD process which is in the range of about 0.1 Å/cycle to about 2 Å/cycle); (b) improved photosensitivity vs known methods, i.e., the improvement of EUV D50 Speed (mJ/cm²) in range of about 1 to 20 mJ/cm², about 5 to 20 mJ/cm², about 10 to 20 mJ/cm².

### SUMMARY

The disclosed and claimed subject matter relates to a method for depositing organotin oxo films that includes, consist essentially of or consists of sequentially:
(a) contacting a substrate with organotin alkoxide precursor vapor of Formula 1:RSn(OR¹)₃ where R and R¹ are each independently selected from a linear C₁ to C₆ alkyl group, a branched C₃ to C₆ alkyl group, a C₃ to C₆ cyclic alkyl group, a C₂ to C₆ alkenyl group, a C₃ to C₆ alkynyl group and a C₄ to C₁₀ aryl group in a deposition reactor;
(b) thereafter introducing organotin amide precursor vapor of Formula 2: R³Sn(NR⁴R⁵)₃ where R³, R⁴ and R⁵ are each independently selected from a linear C₁ to C₆ alkyl group, a branched C₃ to C₆ alkyl group, a C₃ to C₆ cyclic alkyl group, a C₂ to C₆ alkenyl group, a C₃ to C₆ alkynyl group and a C₄ to C₁₀ aryl group in a deposition reactor wherein the R³ group is different from the R group of the organotin amide precursor;
(c) purging the reactor vessel with inert gas;
(d) thereafter introducing a water-containing vapor; and
(e) purging the reactor vessel with inert gas.

The processing steps can be repeated may be repeated to provide a desired thickness of organotin oxo films. Optionally purging the reactor vessel with inert gas may be performed between steps (a) and (b). The amount of organotin alkoxide precursor and organotin amide precursor in step (a) and (b) can be adjusted based their vapor pressures. In some embodiments, the amount of organotin alkoxide precursor of Formula 1 in step (a) is higher than that of organotin amide Formula 2 precursor in step (b). In other embodiments, the amount of organotin alkoxide precursor Formula 1 in step (a) can be lower than that of organotin amide precursor Formula 2 in step (b).

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding FIGURES of the disclosure as further discussed below.

The order of discussion of the different steps described herein has been presented for clarity's sake. In general, the steps disclosed herein can be performed in any suitable order unless indicated otherwise. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the dose curve for the organotin oxo films, demonstrating the two organotin precursors process provide improved photospeed vs a known organotin precursor.

### DEFINITIONS

Unless otherwise stated, the following terms used in the specification and claims shall have the following meanings for this application.

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

The term “alkyl” refers a moiety or group derived via removal of one hydrogen from hydrocarbon. Examples include, but not limited to, methyl, ethyl, n-propyl (n-Pr, Prⁿ or ⁿPr), iso-propyl (i-Pr, Prⁱ or ⁱPr), n-Butyl (n-Bu, ⁿBu or Buⁿ), iso-Butyl (i-Pr, ⁱBu or Buⁱ), t-Butyl (t-Bu, ^{t}Bu or Bu^{t}), n-pentyl (n-Am, ⁿAm or Amⁿ), iso-pentyl (i-Am, ⁱAm or Amⁱ), iso-pentyl (i-Am, ⁱAm or Amⁱ), and t-pentyl (t-Am, ^{t}Am or Am^{t}).

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film. In one or more embodiments, the metal-containing complexes disclosed herein are metal halide complexes, particularly molybdenum chloride complexes.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp. 1-36.

Throughout the description, the term “ALD or ALD-like” refers to a process including, but not limited to, the following processes: a) each reactant including organotin compound precursor and reactive gas is introduced sequentially into a reactor such as a single wafer ALD reactor, semi-batch ALD reactor, or batch furnace ALD reactor; b) each reactant including organotin compound precursor and reactive gas is exposed to a substrate by moving or rotating the substrate to different sections of the reactor and each section is separated by inert gas curtain, i.e., spatial ALD reactor or roll to roll ALD reactor.

As used herein, the term “feature” refers to an opening in a substrate which may be defined by one or more sidewalls, a bottom surface, and upper corners. In various aspects, the feature may be a via, a trench, contact, dual damascene, etc.

The term “about” or “approximately,” when used in connection with a measurable numerical variable, refers to the indicated value of the variable and to all values of the variable that are within ±10% of the stated value.

“Halo” or “halide” refers to a halogen (e.g., F, Cl, Br and I).

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

In one embodiment, the disclosed and claimed subject matter relates to a method for depositing tin-containing films that includes organotin oxo films having two different organotin moieties, for example Me—Sn and t-Bu-Sn. The processing steps can be repeated may be repeated to provide a desired thickness of organotin oxo films.

### Steps (a) and (b): Delivery of Organotin Precursors

### Formula 1 Precursor

As noted above, step (a) of the disclosed and claimed method includes contacting a substrate with organotin alkoxide precursor vapor of Formula 1: RSn(OR¹)₃ where R and R¹ are each independently selected from a linear C₁ to C₆ alkyl group, a branched C₃ to C₆ alkyl group, a C₃ to C₆ cyclic alkyl group, a C₂ to C₆ alkenyl group, a C₃ to C₆ alkynyl group and a C₄ to C₁₀ aryl group.

In one aspect of this embodiment, one or both R and R¹ is a linear C₁ to C₆ alkyl group. In one aspect of this embodiment, one or both R and R¹ is a branched C₃ to C₆ alkyl group. In one aspect of this embodiment, one or both R and R¹ is a C₃ to C₆ cyclic alkyl group. In one aspect of this embodiment, one or both R and R¹ is a C₂ to C₆ alkenyl group. In one aspect of this embodiment, one or both R and R¹ is a C₃ to C₆ alkynyl group. In one aspect of this embodiment, one or both R and R¹ is a C₄ to C₁₀ aryl group.

In one embodiment, the organotin alkoxide precursor vapor of Formula 1 includes, consists essentially of or consists of one or more of MeSn(OPrⁱ)₃, MeSn(OBu^{t})₃, MeSn(OBu^{s})₃, MeSn(OAm^{t})₃, MeSn(OAm^{s})₃, EtSn(OPrⁱ)₃, EtSn(OBu^{t})₃, EtSn(OBu^{s})₃, EtSn(OAm^{t})₃, EtSn(OAm^{s})₃, n-PrSn(OPrⁱ)₃, n-PrSn(OBu^{t})₃, n-PrSn(OBu^{s})₃, n-PrSn(OAm^{t})₃, n-PrSn(OAm^{s})₃, i-PrSn(OPrⁱ)₃, i-PrSn(OBu^{t})₃, i-PrSn(OBu^{s})₃, i-PrSn(OAm^{t})₃, i-PrSn(OAm^{s})₃, n-BuSn(OPrⁱ)₃, n-Bu(OBu^{t})₃, n-BuSn(OBu^{s})₃, n-BuSn(OAm^{t})₃, n-BuSn(OAm^{s})₃, i-BuSn(OPrⁱ)₃, i-BuSn(OBu^{t})₃, i-BuSn(OBu^{s})₃, i-BuSn(OAm^{t})₃, i-BuSn(OAm^{s})₃, t-BuSn(OPrⁱ)₃, t-BuSn(OBu^{t})₃, t-BuSn(OBu^{s})₃, t-BuSn(OAm^{t})₃, t-BuSnSn(OAm^{s})₃, cyclopentylSn(OPrⁱ)₃, cyclopentylSn(OBu^{t})₃, cyclopentylSn(OBu^{s})₃, cyclopentylSn(OAm^{t})₃, cyclopentylSn(OAm^{s})₃ and combinations thereof. In one aspect of this embodiment, the organotin alkoxide precursor is MeSn(OPrⁱ)₃. In one aspect of this embodiment, the organotin alkoxide precursor is MeSn(OBu^{t})₃. In one aspect of this embodiment, the organotin alkoxide precursor is MeSn(OBu^{s})₃. In one aspect of this embodiment, the organotin alkoxide precursor is MeSn(OAm^{t})₃. In one aspect of this embodiment, the organotin alkoxide precursor is MeSn(OAm^{s})₃. In one aspect of this embodiment, the organotin alkoxide precursor is EtSn(OPrⁱ)₃. In one aspect of this embodiment, the organotin alkoxide precursor is EtSn(OBu^{t})₃. In one aspect of this embodiment, the organotin alkoxide precursor is EtSn(OBu^{s})₃. In one aspect of this embodiment, the organotin alkoxide precursor is EtSn(OAm^{t})₃. In one aspect of this embodiment, the organotin alkoxide precursor is EtSn(OAm^{s})₃. In one aspect of this embodiment, the organotin alkoxide precursor is n-PrSn(OPrⁱ)₃. In one aspect of this embodiment, the organotin alkoxide precursor is n-PrSn(OBu^{t})₃. In one aspect of this embodiment, the organotin alkoxide precursor is n-PrSn(OBu^{s})₃. In one aspect of this embodiment, the organotin alkoxide precursor is n-PrSn(OAm^{t})₃. In one aspect of this embodiment, the organotin alkoxide precursor is n-PrSn(OAm^{s})₃. In one aspect of this embodiment, the organotin alkoxide precursor is i-PrSn(OPrⁱ)₃. In one aspect of this embodiment, the organotin alkoxide precursor is i-PrSn(OBu^{t})₃. In one aspect of this embodiment, the organotin alkoxide precursor is i-PrSn(OBu^{s})₃. In one aspect of this embodiment, the organotin alkoxide precursor is i-PrSn(OAm^{t})₃. In one aspect of this embodiment, the organotin alkoxide precursor is i-PrSn(OAm^{s})₃. In one aspect of this embodiment, the organotin alkoxide precursor is n-BuSn(OPrⁱ)₃. In one aspect of this embodiment, the organotin alkoxide precursor is n-Bu(OBu^{t})₃. In one aspect of this embodiment, the organotin alkoxide precursor is n-BuSn(OBu^{s})₃. In one aspect of this embodiment, the organotin alkoxide precursor is n-BuSn(OAm^{t})₃. In one aspect of this embodiment, the organotin alkoxide precursor is n-BuSn(OAm^{s})₃. In one aspect of this embodiment, the organotin alkoxide precursor is i-BuSn(OPrⁱ)₃. In one aspect of this embodiment, the organotin alkoxide precursor is i-BuSn(OBu^{t})₃. In one aspect of this embodiment, the organotin alkoxide precursor is i-BuSn(OBu^{s})₃. In one aspect of this embodiment, the organotin alkoxide precursor is i-BuSn(OAm^{t})₃. In one aspect of this embodiment, the organotin alkoxide precursor is i-BuSn(OAm^{s})₃. In one aspect of this embodiment, the organotin alkoxide precursor is t-BuSn(OPrⁱ)₃. In one aspect of this embodiment, the organotin alkoxide precursor is t-BuSn(OBu^{t})₃. In one aspect of this embodiment, the organotin alkoxide precursor is t-BuSn(OBu^{s})₃. In one aspect of this embodiment, the organotin alkoxide precursor is t-BuSn(OAm^{t})₃. In one aspect of this embodiment, the organotin alkoxide precursor is t-BuSnSn(OAm^{s})₃. In one aspect of this embodiment, the organotin alkoxide precursor is cyclopentylSn(OPrⁱ)₃. In one aspect of this embodiment, the organotin alkoxide precursor is cyclopentylSn(OBu^{t})₃. In one aspect of this embodiment, the organotin alkoxide precursor is cyclopentylSn(OBu^{s})₃. In one aspect of this embodiment, the organotin alkoxide precursor is cyclopentylSn(OAm^{t})₃. In one aspect of this embodiment, the organotin alkoxide precursor is cyclopentylSn(OAm^{s})₃. One preferred organotin alkoxide precursor is MeSn(OBu^{t})₃. Another preferred organotin precursor is MeSn(OAm^{t})₃.

### Formula 2 Precursor

As noted above, step (b) of the disclosed and claimed method follows step (a) and includes introducing an organotin amide precursor vapor of Formula 2: R³Sn(NR⁴R⁵)₃ where R³, R⁴ and R⁵ are each independently selected from a linear C₁ to C₆ alkyl group, a branched C₃ to C₆ alkyl group, a C₃ to C₆ cyclic alkyl group, a C₂ to C₆ alkenyl group, a C₃ to C₆ alkynyl group and a C₄ to C₁₀ aryl group in a deposition reactor where the R³ group is different from the R group of the organotin alkoxide precursor

In one embodiment, the organotin amide precursor vapor of Formula 2 includes, consists essentially of or consists of one or more of MeSn(NMe₂)₃, MeSn(NEt₂)₃, EtSn(NMe₂)₃, EtSn(NEt₂)₃, n-PrSn(NMe₂)₃, i-PrSn(NMe₂)₃, n-BuSn(NMe₂)₃, i-BuSn(NMe₂)₃, s-BuSn(NMe₂)₃, t-BuSn(NMe₂)₃, cyclopentylSn(NMe₂)₃, MeSn(NEtMe)₃, EtSn(NEtMe)₃, n-PrSn(NEtMe)₃, i-PrSn(NEtMe)₃, n-BuSn(NEtMe)₃, i-BuSn(NEtMe)₃, s-BuSn(NEtMe)₃, t-BuSn(NEtMe)₃, cyclopentylSn(NMe₂)₃, cyclopentylSn(NEtMe)₃, i-PrSn(NMe₂)₃ and combinations thereof. In one aspect of this embodiment, the organotin precursor includes MeSn(NMe₂)₃. In one aspect of this embodiment, the organotin amide precursor includes MeSn(NEt₂)₃. In one aspect of this embodiment, the organotin amide precursor includes EtSn(NMe₂)₃. In one aspect of this embodiment, the organotin amide precursor includes EtSn(NEt₂)₃. In one aspect of this embodiment, the organotin amide precursor includes n-PrSn(NMe₂)₃. In one aspect of this embodiment, the organotin amide precursor includes i-PrSn(NMe₂)₃. In one aspect of this embodiment, the organotin amide precursor includes n-BuSn(NMe₂)₃. In one aspect of this embodiment, the organotin amide precursor includes i-BuSn(NMe₂)₃. In one aspect of this embodiment, the organotin amide precursor includes s-BuSn(NMe₂)₃. In one aspect of this embodiment, the organotin amide precursor includes t-BuSn(NMe₂)₃. In one aspect of this embodiment, the organotin amide precursor includes cyclopentylSn(NMe₂)₃. In one aspect of this embodiment, the organotin amide precursor includes MeSn(NEtMe)₃. In one aspect of this embodiment, the organotin amide precursor includes EtSn(NEtMe)₃. In one aspect of this embodiment, the organotin amide precursor includes n-PrSn(NEtMe)₃. In one aspect of this embodiment, the organotin amide precursor includes i-PrSn(NEtMe)₃. In one aspect of this embodiment, the organotin amide precursor includes n-BuSn(NEtMe)₃. In one aspect of this embodiment, the organotin amide precursor includes i-BuSn(NEtMe)₃. In one aspect of this embodiment, the organotin precursor includes s-BuSn(NEtMe)₃. In one aspect of this embodiment, the organotin amide precursor includes t-BuSn(NEtMe)₃. In one aspect of this embodiment, the organotin amide precursor includes cyclopentylSn(NMe₂)₃. In one aspect of this embodiment, the organotin amide precursor includes cyclopentylSn(NEtMe)₃. In one aspect of this embodiment, the organotin amide precursor includes i-PrSn(NMe₂)₃.

### Amount and Ratio of Tin Precursors

The amount of organotin alkoxide precursor and organotin amide precursor in step (a) and (b) can be adjusted based their vapor pressures, flow rates or temperatures of the containers. In some embodiments, the amount of organotin alkoxide precursor of Formula 1 in step (a) is higher than that of organotin amide of Formula 2 precursor in step (b). In other embodiments, the amount of organotin alkoxide precursor of Formula 1 in step (a) is lower than that of organotin amide precursor of Formula 2 in step (b). In other embodiments, the amount of organotin alkoxide precursor of Formula 1 in step (a) is about the same as that of organotin amide precursor of Formula 2 in step (b).

The molar ratio of organotin alkoxide precursor of Formula 1 to organotin amide precursor of Formula 2 is about 0.1 to about 1. In one embodiment, the molar ratio of organotin alkoxide precursor of Formula 1 to organotin amide precursor of Formula 2 is about 0.1. In one embodiment, the molar ratio of organotin alkoxide precursor of Formula 1 to organotin amide precursor of Formula 2 is about 0.2. In one embodiment, the molar ratio of organotin alkoxide precursor of Formula 1 to organotin amide precursor of Formula 2 is about 0.3. In one embodiment, the molar ratio of organotin alkoxide precursor of Formula 1 to organotin amide precursor of Formula 2 is about 0.4. In one embodiment, the molar ratio of organotin alkoxide precursor of Formula 1 to organotin amide precursor of Formula 2 is about 0.5. In one embodiment, the molar ratio of organotin alkoxide precursor of Formula 1 to organotin amide precursor of Formula 2 is about 0.6. In one embodiment, the molar ratio of organotin alkoxide precursor of Formula 1 to organotin amide precursor of Formula 2 is about 0.7. In one embodiment, the molar ratio of organotin alkoxide precursor of Formula 1 to organotin amide precursor of Formula 2 is about 0.8. In one embodiment, the molar ratio of organotin alkoxide precursor of Formula 1 to organotin amide precursor of Formula 2 is about 0.9. In one embodiment, the molar ratio of organotin alkoxide precursor of Formula 1 to organotin amide precursor of Formula 2 is about 1.

In another embodiment, the organotin alkoxide or amide precursor vapor pulse time is from about 0.1 seconds to about 3 seconds. In another embodiment, the organotin alkoxide or amide precursor vapor pulse time is from about 0.3 seconds to about 3 seconds. In another embodiment, the organotin alkoxide or amide precursor vapor pulse time is about 0.1 second. In another embodiment, the organotin alkoxide or amide precursor vapor pulse time is about 0.25 second. In another embodiment, the organotin alkoxide or amide precursor vapor pulse time is about 0.5 second. In another embodiment, the organotin alkoxide or amide precursor vapor pulse time is about 1 second. In another embodiment, the organotin alkoxide or amide precursor vapor pulse time is about 1.5 seconds. In another embodiment, the organotin precursor vapor pulse time is about 2 seconds. Yet, in another embodiment, the organotin precursor vapor pulse time is longer than 2 seconds depending on the volume/design of the reactor chamber.

In another embodiment, a flow of argon and/or other inert gas is employed as a carrier gas to help deliver the organotin precursor vapor to the reaction reactor during the precursor pulsing.

### Step (c): Organotin Precursor Vapor Purging

As noted above, step (c) of the disclosed and claimed method includes (c) purging the reactor vessel with inert gas. Purging with an inert gas following step (b) removes unabsorbed excess organotin precursor vapor from the process reactor. In one embodiment, the purge gas includes argon. In one embodiment, the purge gas includes helium. In another embodiment, the purge gas includes nitrogen.

In one embodiment, for example, the purge time varies from about 1 second to about 90 seconds. In one embodiment, for example, the purge time varies from about 15 seconds to about 90 seconds. In one embodiment, for example, the purge time varies from about 15 seconds to about 60 seconds. In another embodiment, the purge time is about 30 seconds. In another embodiment, the purge time is about 60 seconds. In another embodiment, the purge time is about 90 seconds.

### Step (d): Water-Containing Vapor Reactant

As noted above, step (d) of the disclosed and claimed method includes contacting the substrate with a water-containing vapor to form an organotin oxo network layer.

In one embodiment, for example, the water-containing vapor pulse time varies from about 0.5 seconds to about 5 seconds. In one embodiment, for example, the water-containing vapor pulse time is about 2.5 seconds. In one embodiment, for example, the water-containing vapor pulse time is about 5 seconds. Yet, in another embodiment, the organotin precursor vapor pulse time is longer than 5 seconds depending on the volume/design of the vapor deposition reactor chamber.

### Step (e): Purging Step

As noted above, step (e) of the disclosed and claimed method includes purging the reactor vessel with inert gas following the water-containing vapor introduction. Purging with an inert gas following step (d) removes any remaining material used for the water-containing vapor treatment from the process reactor. In one embodiment, the purge gas includes argon. In one embodiment, the purge gas includes helium. In another embodiment, the purge gas includes nitrogen.

In one embodiment, for example, the purge time varies from about 1 second to about 90 seconds. In one embodiment, for example, the purge time varies from about 15 seconds to about 90 seconds. In one embodiment, for example, the purge time varies from about 15 seconds to about 60 seconds. In another embodiment, the purge time is about 30 seconds. In another embodiment, the purge time is about 60 seconds. In another embodiment, the purge time is about 90 seconds. Yet, in another embodiment, the purge time is longer than 90 seconds depending on the volume/design of the vapor deposition reactor chamber.

### Photosensitivity

Radiation sensitive resists are films designed to change their solubility when exposed to radiation. In a further aspect, the disclosed and claimed process further includes exposing the tin-containing films to a radiation source selected from the group of KrF (248 nm), ArF (193 nm), VUV (157 nm), EUV (13 nm), E-beam, X-ray and ion beam. Patterns are formed by selectively exposing only the desired areas of the film. The films are exposed to radiation (photons in the case of EUV, electrons in the case of EBL), then the sample is then washed in a solvent (called a developer) that dissolves away either the exposed (positive-tone resists) or unexposed (negative-tone resist) region. In either the case, the pattern of radiation exposure has now become the pattern of presence or absence of resist on the substrate. The resist can then be used as a mask for further semiconductor processing steps, such as etching or deposition.

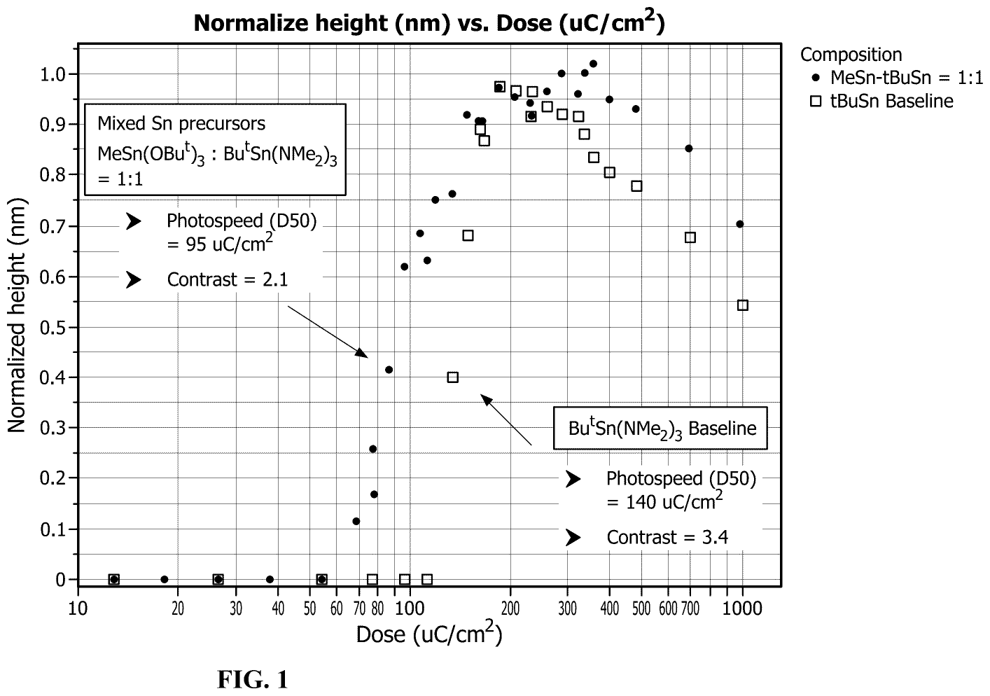

In FIG. 1, illustrates a graph of dose matrix test. This graph is generated by exposing an array of identical patterns on a sample with a resist film. The dose, or amount of radiation provided, is different at each point in the array. FIG. 1 provides a plot for each dose the height of the resist remaining after development, but we could also use other measures of quality of the patterns produced. As can be seen, the sensitivity of the resist by looking at the lowest dose that still provides the desired patterns. Higher sensitivity (responding at a lower dose) is generally preferred. Also of interest is the contrast, a measure of how quickly the response of the film increases as the dose exceeds the minimum dose required.

### Operating Conditions

As noted above, the disclosed and claimed tin deposition process can be effectively conducted under very favorable ALD conditions.

In one embodiment the substrate is one or more of amorphous carbon, silicon oxide (SiO₂), aluminum oxide (Al₂O₃), titanium nitride (TiN), hafnium oxide (HfO₂), zirconium oxide (ZrO₂), an underlayer that includes two or more elements such as Si, O, C, N, Ge, Sn, Sb and Te and combination thereof is heated on a heater stage in a reaction reactor that is exposed to the organotin precursor initially to allow the complex to chemically adsorb onto the surface of the substrate. In one embodiment, the substrate temperature is from about 25° C. to about 300° C. In a further aspect of this embodiment, the substrate temperature is from about 25° C. to about 250° C. In a further aspect of this embodiment, the substrate temperature is from about 25° C. to about 200° C., or from about 50° C. to about 150° C., or from about 50° C. to about 130° C., or from about 60° C. to about 130° C., or from about 70° C. to about 120° C., or from about 70° C. to about 110° C. Not bounded by theory, it is expected the substrate temperatures lower than 120° C. may facilitate the reaction of organotin precursors and water on the substrate surface, thus promoting polymeric formation of organotin oxo film.

In another embodiment, the reactor pressure for depositions according to the disclosed and claimed process is ≤ about 100 torr. In another embodiment, the reactor pressure for depositions according to the disclosed and claimed process is ≤ about 75 torr. In another embodiment, the reactor pressure for depositions according to the disclosed and claimed process is ≤ about 50 torr. In another embodiment, the reactor pressure for depositions according to the disclosed and claimed process is ≤ about 40 torr. In another embodiment, the reactor pressure for depositions according to the disclosed and claimed process is ≤ about 30 torr. In a further aspect of this embodiment, the reactor pressure is ≤ about 20 torr. In a further aspect of this embodiment, the reactor pressure is ≤ about 10 torr. In a further aspect of this embodiment, the reactor pressure is ≤ about 5 torr.

### Exemplary Processes

In one exemplary embodiment of the disclosed and claimed subject matter, organotin oxo films are formed on a substrate using an ALD/ALD-like deposition method. The substrate and reactor are heated to a temperature of about 25° C. to about 200° C. and the reactor pressure is (optionally) maintained at a about 100 torr or less. The steps of the deposition include:
(a) contacting a substrate with organotin alkoxide precursor vapor of Formula 1: RSn(OR¹)₃ where R and R¹ are each independently selected from a linear C₁ to C₆ alkyl group, a branched C₃ to C₆ alkyl group, a C₃ to C₆ cyclic alkyl group, a C₂ to C₆ alkenyl group, a C₃ to C₆ alkynyl group and a C₄ to C₁₀ aryl group in a deposition reactor;
(b) thereafter introducing organotin amide precursor vapor of Formula 2: R³Sn(NR⁴R⁵)₃ where R³, R⁴ and R⁵ are each independently selected from a linear C₁ to C₆ alkyl group, a branched C₃ to C₆ alkyl group, a C₃ to C₆ cyclic alkyl group, a C₂ to C₆ alkenyl group, a C₃ to C₆ alkynyl group and a C₄ to C₁₀ aryl group in a deposition reactor wherein the R³ group is different from the R group of the organotin alkoxide precursor;
(c) purging the reactor vessel with inert gas;
(d) thereafter introducing a water-containing vapor; and
(e) purging the reactor vessel with inert gas.
   Steps (a) to (e) may be repeated to provide a desired thickness of organotin oxo films which can range from about 50 Å to about 1000 Å, about 50 Å to about 500 Å, about 50 Å to about 300 Å or about 50 Å to about 200 Å. In one embodiment, the films formed by the methods described herein have a thickness of about 50 Å to about 1000 Å. In another aspect of this embodiment, the films formed by the methods described herein have a thickness of about 50 Å to 500 Å. In another aspect of this embodiment, the films formed by the methods described herein have a thickness of about 50 Å to 300 Å. In another aspect of this embodiment, the films formed by the methods described herein have a thickness of about, 50 Å to 200 Å. In another aspect of this embodiment, argon (Ar) is used as the purge gas in steps (c) and (e). In another aspect of this embodiment, the organotin oxo film is deposited using an organotin alkoxide precursor selected from the group of MeSn(OPrⁱ)₃, MeSn(OBu^{t})₃, MeSn(OBu^{s})₃, MeSn(OAm^{t})₃, MeSn(OAm^{s})₃. In another aspect of this embodiment, the organotin oxo film is deposited using an organotin amide precursor selected from the group of i-PrSn(NMe₂)₃, n-BuSn(NMe₂)₃, i-BuSn(NMe₂)₃, s-BuSn(NMe₂)₃, t-BuSn(NMe₂)₃. In another aspect of this embodiment, the organotin oxo film includes, consists essentially of or consists of Me—Sn and t-Bu-Sn moieties. In another aspect of this embodiment, the organotin oxo film includes, consists essentially of or consists of Me—Sn and i-Pr—Sn moieties.

### EXAMPLES

Reference will now be made to more specific embodiments of the present disclosure and experimental results that provide support for such embodiments. The examples given below more fully illustrate the disclosed and claimed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Working Examples

Conditions: Deposition temperature was 90° C. to 130° C.; reactor pressure was about 2 torr; Bu^{t}Sn(NMe₂)₃ and MeSn(OBu^{t}) were employed as organotin precursor. The molar ratio of Bu^{t}Sn(NMe₂)₃ and MeSn(OBu^{t}) vapors were adjusted close to 1.

### Comparable Example 1: Single Precursor of Formula 1

The ALD-like process was conducted as MeSn(OBu^{t})₃ vapor (5 seconds)—Purge (60 seconds)—water vapor (0.5 second)—Purge (90 seconds).

### Comparable Example 2: Single Precursor of Formula 2

The ALD-like process was conducted as Bu^{t}Sn(NMe₂)₃ vapor (5 seconds)—Purge (60 seconds)—water vapor (0.1 second)—Purge (90 seconds).

### Comparable Example 3: Precursor of Formula 2 Before Precursor of Formula 1

The ALD-like process was conducted as Bu^{t}Sn(NMe₂)₃ vapor (2.5 seconds)—MeSn(OBu^{t})₃ vapor (2.5 seconds)—Purge (60 seconds)—water vapor (0.5 second)—Purge (90 seconds).

### Working Example 1: Precursor of Formula 1 Before Precursor of Formula 2

The ALD-like process was conducted as MeSn(OBu^{t})₃ vapor (2.5 seconds)—Bu^{t}Sn(NMe₂)₃ vapor (2.5 seconds)—Purge (60 seconds)—water vapor (0.5 second)—Purge (90 seconds).

Table 1 summarizes the deposition conditions and resulting organotin oxo films composition for the above examples.

TABLE 1

| | Pedestal | Sequence (Sec.) | Solubility | XPS Compositions | | |
|---|---|---|---|---|---|---|
| Precursor | Temp (° C.) | Sn—Ar—H₂O—Ar | 2-Heptanone | Sn % | C % | O % |
| MeSn(O^{t}Bu)₃ | 110 | 5-60-0.5-90 | Not Soluble | 19.5-22.8 | 45-36 | 35.7-41.2 |
| (“OB”) | | | | | | |
| ^{t}BuSn(NMe₂)₃ | 90-130 | 5-60-0.1-90 | Soluble | 12.3-13.3 | 61.8-60.7 | 25.9-26 |
| (“tB”) | | | | | | |
| tB-OB (1:1) | 110 | (2.5/2.5)-60-0.5-90 | Limited/Not | 13.0 | 61.6 | 25.3 |
| | | | Soluble | | | |
| OB-tB (1:1) | 110 | (2.5/2.5)-60-0.5-90 | Soluble | 12.5 | 62.1 | 25.4 |

As demonstrated in Table 1, the solubility of resulting organotin oxo films are different depending on sequence of precursor exposures in the ALD-like processes. If the resulting organotin oxo film is not soluble, it is not suitable as photopatternable or a radiation-sensitive material for high resolution patterning process. Importantly working example 1 demonstrates the solubility of the resulting organotin oxo film can be tuned via changing the order of introducing organotin precursor. It is also expected that the resulting organotin oxo films can be further adjusted via changing the pulsing time of the organotin alkoxide precursor and the organotin amide precursor, allowing deposition of organotin oxo films with different ratios of alkyl-tin moieties with different alkyl groups unlike what is disclosed in U.S. Ser. No. 10/732,505 where the alkyl groups in the resulting organotin oxo films would be reduced because the second precursor does not contain any alkyl group bonded to the tin atom.

The plot in FIG. 1 for each dose the height of the resist remaining after development. The sensitivity of the resist is evaluated by looking at the lowest dose that still provides the desired patterns. Higher sensitivity (responding at a lower dose) is generally preferred. Also of interest is the contrast, a measure of how quickly the response of the film increases as the dose exceeds the minimum dose required. Clearly the EBL results for the two organotin ALD-like process in working example 1 demonstrates improved photosensitivity than one organotin in the known methods, i.e., Bu^{t}Sn(NMe₂)₃ baseline process. Importantly it is believed that the remaining alkyl-tin moieties in the as-deposited films play an important role for the photosensitivity as well as chemical properties of the resulting organotin oxo films after light exposure using E-beam or EUV, it is possible to provide further improved photosensitivity via changing the ratio of two different alkyl-tin moieties via adjusting the ratio of the organotin alkoxide precursor vapor and the organotin amide precursor vapor during delivery of the two precursors.

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

What is claimed is:

1. A method for depositing tin-containing films that comprises sequentially of the steps of:
(a) contacting a substrate with organotin alkoxide precursor vapor of Formula 1: RSn(OR¹)₃ where R and R¹ are each independently selected from a linear C₁ to C₆ alkyl group, a branched C₃ to C₆ alkyl group, a C₃ to C₆ cyclic alkyl group, a C₂ to C₆ alkenyl group, a C₃ to C₆ alkynyl group and a C₄ to C₁₀ aryl group in a deposition reactor;
(b) thereafter introducing organotin amide precursor vapor of Formula 2: R³Sn(NR⁴R⁵)₃ where R³, R⁴ and R⁵ are each independently selected from a linear C₁ to C₆ alkyl group, a branched C₃ to C₆ alkyl group, a C₃ to C₆ cyclic alkyl group, a C₂ to C₆ alkenyl group, a C₃ to C₆ alkynyl group and a C₄ to C₁₀ aryl group in a deposition reactor wherein the R³ group is different from the R group of the organotin alkoxide precursor;
(c) purging the reactor vessel with inert gas;
(d) thereafter introducing a water-containing vapor; and
(e) purging the reactor vessel with inert gas.

2. The process of claim 1, wherein the organotin alkoxide precursor vapor of Formula 1 comprises one or more of MeSn(OPrⁱ)₃, MeSn(OBu^{t})₃, MeSn(OBu^{s})₃, MeSn(OAm^{t})₃, MeSn(OAm^{s})₃, EtSn(OPrⁱ)₃, EtSn(OBu^{t})₃, EtSn(OBu^{s})₃, EtSn(OAm^{t})₃, EtSn(OAm^{s})₃, n-PrSn(OPrⁱ)₃, n-PrSn(OBu^{t})₃, n-PrSn(OBu^{s})₃, n-PrSn(OAm^{t})₃, n-PrSn(OAm^{s})₃, i-PrSn(OPrⁱ)₃, i-PrSn(OBu^{t})₃, i-PrSn(OBu^{s})₃, i-PrSn(OAm^{t})₃, i-PrSn(OAm^{s})₃, n-BuSn(OPrⁱ)₃, n-Bu(OBu^{t})₃, n-BuSn(OBu^{s})₃, n-BuSn(OAm^{t})₃, n-BuSn(OAm^{s})₃, i-BuSn(OPrⁱ)₃, i-BuSn(OBu^{t})₃, i-BuSn(OBu^{s})₃, i-BuSn(OAm^{t})₃, i-BuSn(OAm^{s})₃, t-BuSn(OPrⁱ)₃, t-BuSn(OBu^{t})₃, t-BuSn(OBu^{s})₃, t-BuSn(OAm^{t})₃, t-BuSnSn(OAm^{s})₃,
cyclopentylSn(OPrⁱ)₃, cyclopentylSn(OBu^{t})₃, cyclopentylSn(OBu^{s})₃, cyclopentylSn(OAm^{t})₃, cyclopentylSn(OAm^{s})₃ and combinations thereof.

3. The process of claim 1, wherein the organotin amide precursor vapor of Formula 2 comprises one or more of MeSn(NMe₂)₃, MeSn(NEt₂)₃, EtSn(NMe₂)₃, EtSn(NEt₂)₃, n-PrSn(NMe₂)₃, i-PrSn(NMe₂)₃, n-BuSn(NMe₂)₃, i-BuSn(NMe₂)₃, s-BuSn(NMe₂)₃, t-BuSn(NMe₂)₃, cyclopentylSn(NMe₂)₃, MeSn(NEtMe)₃, EtSn(NEtMe)₃, n-PrSn(NEtMe)₃, i-PrSn(NEtMe)₃, n-BuSn(NEtMe)₃, i-BuSn(NEtMe)₃, s-BuSn(NEtMe)₃, t-BuSn(NEtMe)₃, cyclopentylSn(NMe₂)₃, cyclopentylSn(NEtMe)₃, i-PrSn(NMe₂)₃ and combinations thereof.

4. The process of claim 1, wherein purging the reactor vessel with inert gas between steps (a) and (b).

5. The process of claim 1, wherein the step (c) purge gas comprises argon or nitrogen.

6. The process of claim 1, wherein the step (d) water-containing vapor pulse time varies from about 0.5 seconds to about 5 seconds.

7. The process of claim 1, wherein the step (e) purge time varies from about 1 second to about 90 seconds.

8. The process of claim 1, wherein the step (e) purge gas comprises argon.

9. The process of claim 1, wherein the amount of organotin alkoxide precursor of Formula 1 in step (a) is higher than that of organotin amide of Formula 2 precursor in step (b).

10. The process of claim 1, wherein the amount of organotin alkoxide precursor of Formula 1 in step (a) is lower than that of organotin amide precursor of Formula 2 in step (b).

11. The process of claim 1, wherein the amount of organotin alkoxide precursor of Formula 1 in step (a) is about the same as that of organotin amide precursor of Formula 2 in step (b).

12. The process of claim 1, wherein the molar ratio of organotin alkoxide precursor of Formula 1 to organotin amide precursor of Formula 2 is about 0.1 to about 1.

13. A photopatternable or a radiation-sensitive organotin oxo film deposited by the process of claim 1.

14. The organotin oxo film of claim 13, wherein the organotin oxo film is deposited using an organotin alkoxide precursor selected from the group of MeSn(OPrⁱ)₃, MeSn(OBu^{t})₃, MeSn(OBu^{s})₃, MeSn(OAm^{t})₃, MeSn(OAm^{s})₃.

15. The organotin oxo film of claim 13, wherein the organotin oxo film is deposited using an organotin amide precursor selected from the group of i-PrSn(NMe₂)₃, n-BuSn(NMe₂)₃, i-BuSn(NMe₂)₃, s-BuSn(NMe₂)₃, t-BuSn(NMe₂)₃.

16. The organotin oxo film of claim 13, wherein the organotin oxo film includes, consists essentially of or consists of Me—Sn and t-Bu-Sn moieties.

17. The organotin oxo film of claim 13, wherein the organotin oxo film includes, consists essentially of or consists of Me—Sn and i-Pr—Sn moieties.
